(19) United States
(12) Patent Application Publication
(10) Pub. No.: US 2019/0278698 A1
(43) Pub. Date: Sep. 12, 2019

(54) Autonomous Vehicle Simulation And Testing

(71) Applicant: RightHook, Inc., San Jose, CA (US)

(72) Inventors: Warren Ahner, San Jose, CA (US); Jonathan Thomas Mullen, San Jose, CA (US)

(21) Appl. No.: 16/295,921

(22) Filed: Mar. 7, 2019

Related U.S. Application Data
(60) Provisional application No. 62/639,896, filed on Mar. 7, 2018.

(51) Int. Cl. G06F 11/36; G06F 17/50; G05D 1/00; G05D 1/02

(52) U.S. Cl. CPC G06F 11/3664; G06F 17/5009; G05D 2201/0213; G05D 1/0088; G05D 1/0221; G06F 17/5095

(57) ABSTRACT

A method for providing simulation testing. The method may include receiving a customer request to generate a virtual environment for testing a robot of the customer. The virtual environment may be automatically generated by a service provider in accordance with the request. The customer may interface with the virtual environment of the service provider to iteratively test the robot in the virtual environment. This testing may generate simulation results that reflect interactions between the robot and the virtual environment. The simulation results may be communicated from the service provider to the customer. A corresponding system and computer program product are also disclosed herein.

### PRIORITY INFORMATION

This application claims priority to U.S. Application Ser. No. 62/639,896 filed on Mar. 7, 2018, entitled, “Autonomous Vehicle Simulation And Testing.”

### BACKGROUND

### Field of the Invention

This invention relates to systems and methods for simulating and testing performance of a robot.

### Background of the Invention

Autonomous vehicles are an emerging technology with enormous potential. Being an immature technology, however, fully autonomous vehicles still require extensive testing to demonstrate their safety for general on-road use.

In a virtual reality environment, both ordinary scenes and extraordinary scenes that would rarely occur in real life can be generated and repeated an endless number of times. For example, virtual reality environments may simulate traffic situations and conditions that would otherwise only be encountered by driving billions of miles across a wide variety of locations, during varied times of the year. Virtual reality environments may also generate situations that in real life would require negotiating dangerous events, accidents, and obstacles that could cause real harm. Finally, virtual reality environments may be fine-tuned as needed to test a single variable while leaving all other variables untouched.

Accordingly, what are needed are systems and methods to provide efficient and cost-effective testing of autonomous vehicles and other robots. Also what are needed are systems and methods to generate virtual environments according to customer specifications and direct testing to particular data of interest. Ideally, such systems and methods would enable a customer to interface with the virtual environment as desired. Such systems and methods are disclosed and claimed herein.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1 is a high-level block diagram showing one example of a computing system in which a system and method in accordance with the invention may be implemented;

FIG. 2 is a high-level block diagram of an embodiment of automated environment creation in accordance with the invention;

FIG. 3 is a flow chart depicting initialization of a simulation given a scenario in accordance with certain embodiments of the invention;

FIG. 4 is a flow chart showing a process for simulating performance in a test environment in accordance with certain embodiments of the invention;

FIG. 5 is an architecture diagram of one embodiment of a system for simulating performance in accordance with the invention;

FIG. 6 is a flow chart showing a process for launching simulation in accordance with certain embodiments of the invention;

FIG. 7 is a flow chart showing one embodiment of a process for simulating autonomous vehicle performance in accordance with the invention;

FIG. 8 is a flow chart showing a process for utilizing an HD map uploaded by a customer in accordance with embodiments of the invention;

FIG. 9 is a flow chart showing one embodiment of creating a generalized point cloud in accordance with the invention; and

FIG. 10 is a high-level block diagram of one embodiment for augmenting actual sensor measurements with hallucinated sensor measurements in accordance with the invention.

### DETAILED DESCRIPTION

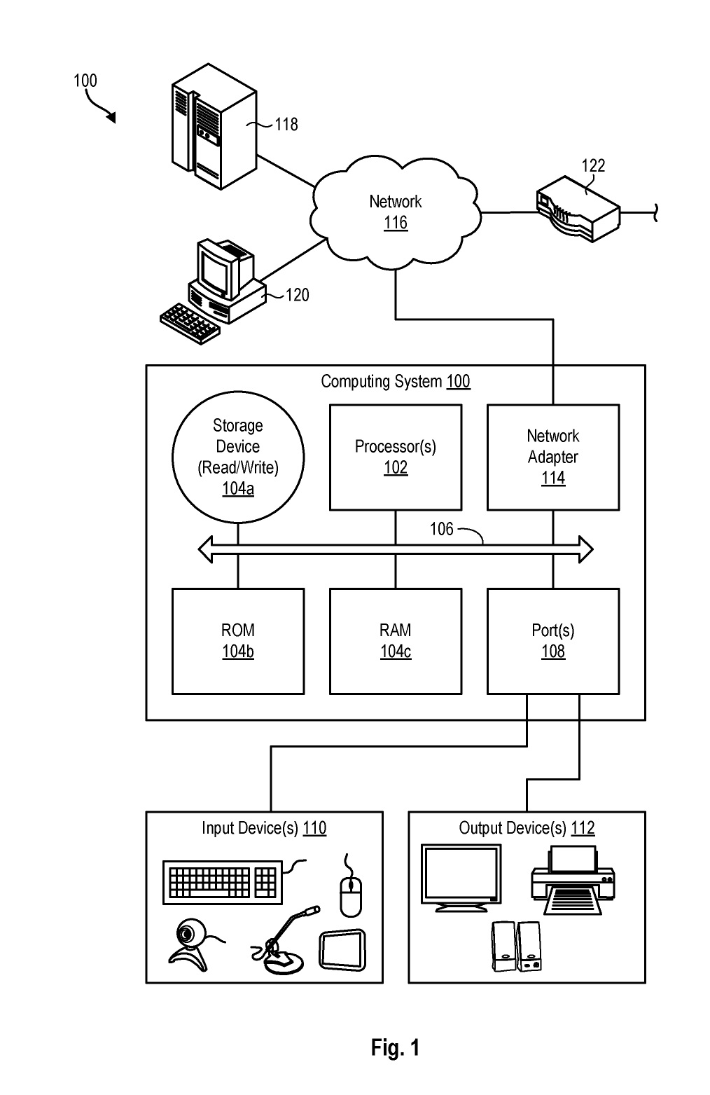

Referring to FIG. 1, one example of a computing system 100 is illustrated. The computing system 100 is presented to show one example of an environment where a system and method in accordance with the invention may be implemented. The computing system 100 may be embodied as a mobile device 100 such as a smart phone or tablet, a desktop computer, a workstation, a server, or the like. The computing system 100 is presented by way of example and is not intended to be limiting. Indeed, the systems and methods disclosed herein may be applicable to a wide variety of different computing systems in addition to the computing system 100 shown. The systems and methods disclosed herein may also potentially be distributed across multiple computing systems 100.

As shown, the computing system 100 includes at least one processor 102 and may include more than one processor 102. The processor 102 may be operably connected to a memory 104. The memory 104 may include one or more non-volatile storage devices such as hard drives 104a, solid state drives 104a, CD-ROM drives 104a, DVD-ROM drives 104a, tape drives 104a, or the like. The memory 104 may also include non-volatile memory such as a read-only memory 104b (e.g., ROM, EPROM, EEPROM, and/or Flash ROM) or volatile memory such as a random access memory 104c (RAM or operational memory). A bus 106, or plurality of buses 106, may interconnect the processor 102, memory devices 104, and other devices to enable data and/or instructions to pass therebetween.

To enable communication with external systems or devices, the computing system 100 may include one or more ports 108. Such ports 108 may be embodied as wired ports 108 (e.g., USB ports, serial ports, Firewire ports, SCSI ports, parallel ports, etc.) or wireless ports 108 (e.g., Bluetooth, IrDA, etc.). The ports 108 may enable communication with one or more input devices 110 (e.g., keyboards, mice, touchscreens, cameras, microphones, scanners, storage devices, etc.) and output devices 112 (e.g., displays, monitors, speakers, printers, storage devices, etc.). The ports 108 may also enable communication with other computing systems 100.

In certain embodiments, the computing system 100 includes a wired or wireless network adapter 114 to connect the computing system 100 to a network 116, such as a LAN, WAN, or the Internet. Such a network 116 may enable the computing system 100 to connect to one or more servers 118, workstations 120, personal computers 120, mobile computing devices, or other devices. The network 116 may also enable the computing system 100 to connect to another network by way of a router 122 or other device 122. Such a router 122 may allow the computing system 100 to communicate with servers, workstations, personal computers, or other devices located on different networks.

Embodiments of the invention may generate a virtual reality environment for testing performance of a robot or other machine capable of influencing the real world. The robot may include various sensors to operate in the real world. Embodiments of the present invention may automatically create a virtual environment within which such sensors may perform and be tested.

In one embodiment, the robot may be an autonomous vehicle, for example. Embodiments of the invention may automatically generate a virtual environment for testing sensors associated with the autonomous vehicle. The customer may specify that the autonomous vehicle is a specific make and model (i.e., a Ford Fusion), with a specific number and type of sensors (i.e., four cameras and a lidar on the roof). The customer may further specify that performance of the autonomous vehicle be tested in the virtual testing environment at a particular time of day or time of year (i.e., at night in the winter). The testing results may then be sent back to the customer to act on as desired.

In another embodiment, the robot may be, for example, a smart garage door having a motor capable of moving the door. The sensors may include a camera, and embodiments of the invention may automatically generate a virtual environment surrounding the garage door. At specified time steps, the view from the camera may be sent to the customer, and the customer may determine an appropriate motor response.

As used herein, the term “cosimulation process” refers to any physics and/or sensor simulation process known to those in the art.

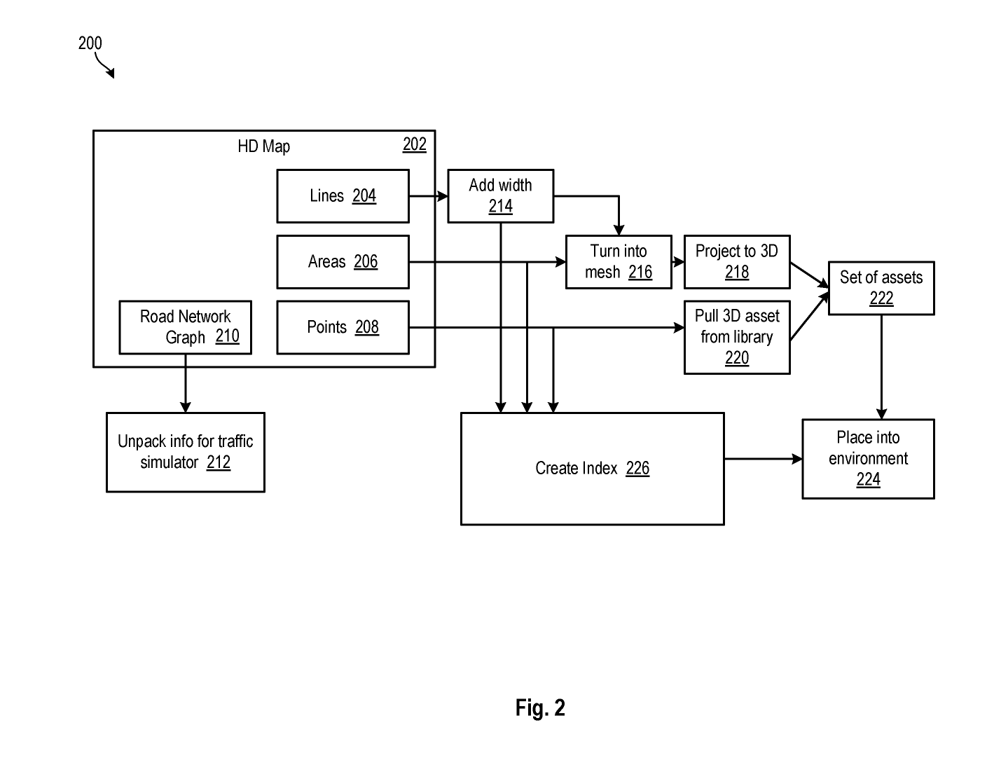

As shown in FIG. 2, a method 200 for automated virtual environment generation may begin by receiving or generating a high-definition map 202 of a particular region or location. In some embodiments, the high-definition map 202 may be uploaded to a website by a customer. In other embodiments, the customer may select a high-definition map 202 from various pre-generated high-definition maps 202. In still other embodiments, an appropriate high-definition map 202 may be automatically selected or generated according to the robot or technology being tested. In any case, the high-definition map 202 may be augmented to include a road network graph 210 having information for use in a traffic simulation 212 created in accordance with embodiments of the invention.

The high-definition map 202 may also include various geometric features, including lines 204, shapes or areas 206 (i.e., polygons), and points 208. Points 208 may represent, for example, locations for specific items or assets, such as a mailbox or pole. In certain embodiments, a 3D representation of the item or asset corresponding to the point 208 may be pulled from a library 220 or submitted by the customer and added to the virtual environment.

In some embodiments, lines 204 may be turned into polygons or other shapes by first giving them some kind of width 214. Shapes or areas 206 may include, for example, the shape and location of a road. Some embodiments of the invention may take all the 2D shapes and areas 206 and mesh 216 those into big sets of connected triangles. A height may then be assigned to each vertex in the mesh 216 to convert it into a 3D object 218. Each 3D object 218 rendered or pulled from the library 220 may be included in a set 222 of all assets for use in the virtual environment.

Upon placement 224 into the virtual environment, an index 226 may be created that includes all of the 3D objects 218, as well as their placement locations. In some embodiments, the index 226 may also tag each 3D object 218 with the properties associated with it during the simulation, such as particular properties or materials intrinsic to the 3D object 218 that respond to radar or lidar. This information may also be stored in the index 226 or scene model for 3D objects 218.

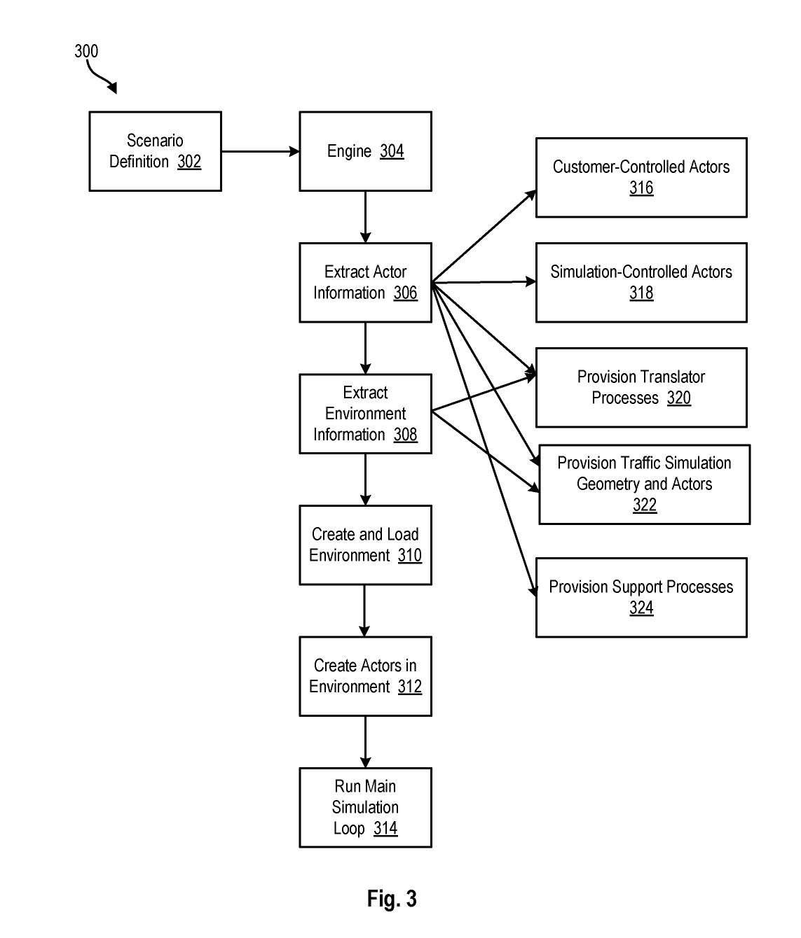

Referring to FIG. 3, some embodiments of the invention may include a method 300 for generating a scenario for use in simulation testing. The scenario may include the virtual environment, as well as all of the various actors acting within the environment during the simulation. In some embodiments, a scenario definition 302 may include a behavioral profile for non-customer-controlled actors (i.e., is the driver sober, aggressive, or distracted), as well as intent (i.e., where does the actor want to go). In one embodiment, a customer may define 302 a scenario as a virtual environment including two customer-controlled autonomous vehicles tested simultaneously, a customer-controlled pedestrian, ninety-eight simulation-controlled vehicles, and fifty simulation-controlled pedestrians, for example.

This scenario definition 302 may be sent from the customer to a simulation engine 304. The engine 304 may extract actor information 306 to identify customer-controlled actors 316 and simulation-controlled actors 318, for example. In some embodiments, translator processes may be provisioned 320 to communicate state and measurement information from the simulation middleware to the customer middleware (the two autonomous vehicles, for example, or other customer-controlled actors).

In certain embodiments, customer middleware may include a collection of various nodes and processes communicating on a standard bus. A standard bus may have a named topic, such as “Camera 1.” While ordinarily the information on the “Camera 1” topic would come from a hardware driver, embodiments of the invention may instead send information from the simulation on the “Camera 1” topic. Such information may be bridged from the simulation middleware to the customer middleware.

In some embodiments, the sensors intended for use during simulation may not be known until they are provisioned based on customer information right before run-time. Accordingly, certain embodiments of the invention may provision 320 many translation processes that run live for the duration of the simulation. In some embodiments, actors that are not controlled by the customer may be provisioned 322 using the traffic simulation, or may be left static. Simulation-controlled actors 318 may have substantially the same properties as customer-controlled actors 316, with the exception of communication permissions. Traffic simulation geometry and associated actors and information may then be provisioned 322, as well as associated support processes 324.

From the scenario definition 302, environment information may be extracted 308. Environment information may include, for example, metadata such as location, time of day, weather, and the like. A virtual environment may then be created 310 and loaded as a 3D model. In some embodiments, actors may be appropriately represented and positioned 312 within the environment, after which a simulation loop may run 314.

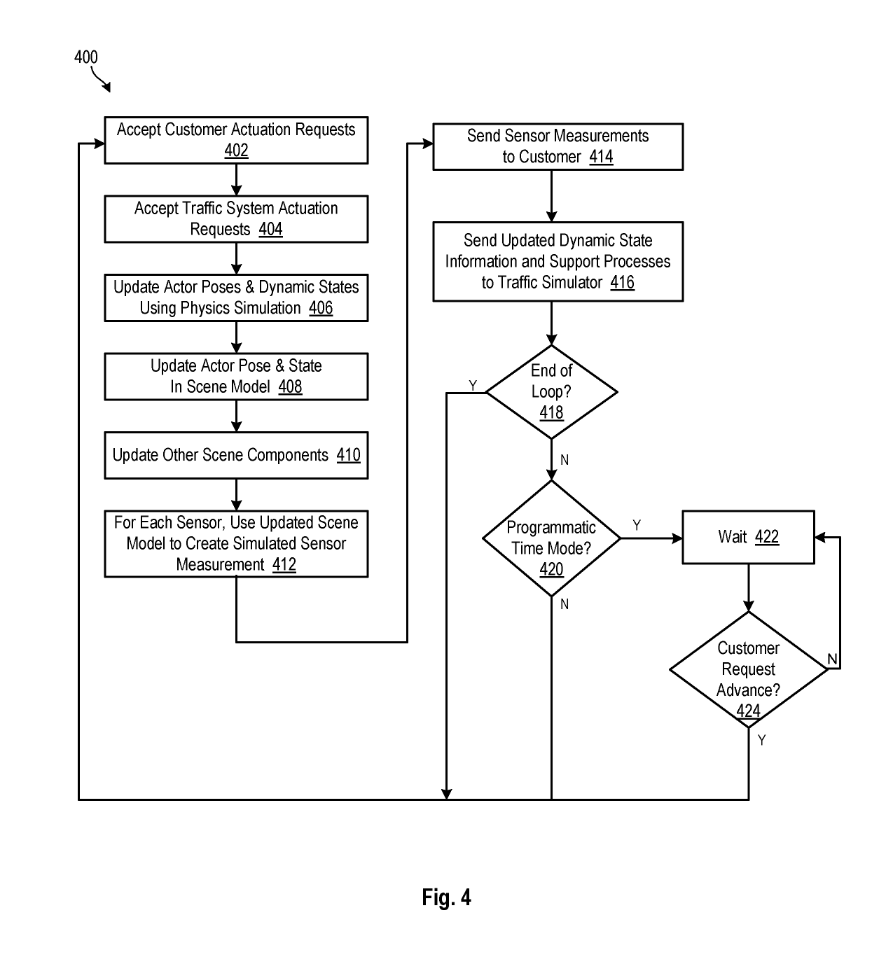

FIG. 4 depicts a process 400 for simulating performance of a robot, such as an autonomous vehicle, in a test environment in accordance with embodiments of the invention. In certain embodiments, this process 400 may be the main loop that is run during simulation. Essentially, the simulation may create a time series of state and measurement information as it runs. Information may be received from a customer with respect to how the robot or vehicle should operate, and the virtual environment may be created and/or updated based on that information. In some embodiments, sensor signals may be updated based on the updated virtual environment, and that information may be forwarded to the customer.

In operation, the process 400 may begin by accepting 402 a customer request for actuation. The request may include information regarding the scene and changes that should be made to the scene. In some embodiments, a simulation traffic system may request actuation 404. Upon receiving one or both requests 402, 404, the system may update 406 locations and orientations of each of the actors, as well as their dynamic states. Dynamic states may include, for example, whether there are lights on, whether brake lights are on, whether windshield wipers are active, and the like.

Both positions and locations of actors and dynamic states may be directly requested by the customer, or may be determined in accordance with physics simulation techniques 406. For example, in some embodiments, the customer may instruct the system to turn the wheel ten degrees, and to activate the right turn signal. Physics simulation techniques 406 may determine that, based on the customer request to set the steering angle at ten degrees, the vehicle should be moved forward twenty meters and to the right one meter at the set time period. The output of the physics simulation may be used to update 408 the scene model. Other scene components may also be updated 410, such as the state of traffic lights, or the time of day. In some embodiments, for each simulated sensor, the system may use the updated scene model to create 412 a simulated sensor measurement that reflects what the sensor senses or otherwise detects.

As previously mentioned, each sensor being tested in the simulation may be included in the scenario definition initially provided by the customer. For each sensor, the system may create 412 measurements corresponding to the sensor for the time step. These measurements may be computed based on the location and orientation of the sensor, the scene model, and a mathematical model of the sensor, for example. In certain embodiments, the sensor measurements may be sent 414 to the customer, while some of the updated information, such as the updated dynamic state information and support processes, may be sent 416 to the simulator traffic system and supporting processes.

In one execution mode, this process 400 may query 418 whether to run as a continuous loop. If yes, the process 400 may run for a certain period of time or until it receives an instruction to stop. In this embodiment, the process 400 may run as fast as possible to maximize the number of times the sensors' measurements are simulated and sent to the customer's middleware within a certain period of time.

Another execution mode, called “Programmatic Time Mode 420” may execute the process a single time. In this embodiment, the process 400 may only repeat upon receiving a request to do so from the customer. In certain embodiments, Programmatic Time Mode enables the customer to test the closed-loop system free from real-time constraints. This execution mode may be desirable when, for example, there is a very large sensor set that renders real-time constraints difficult to satisfy. Similarly, there may be instances where the customer's prototype software is not yet fast enough to satisfy real-time constraints. In these and other instances, Programmatic Time Mode 420 may provide a way of relieving real-time constraints while maintaining accurate time-stepping.

In one embodiment of Programmatic Time Mode, for example, a time interval or step may be extended or reduced as needed. For example, in one embodiment, a 0.004 second simulation may be performed in five seconds. In another embodiment, where it is possible to perform computations in less time than the specified time step, the simulation may be run faster than real time may allow. In any case, the process 400 may wait 422 after completion of one execution for a customer instruction. If the customer requests 424 the process 400 to advance, the process 400 may execute an additional time. If no customer request is received, the process 400 may continue to wait 422.

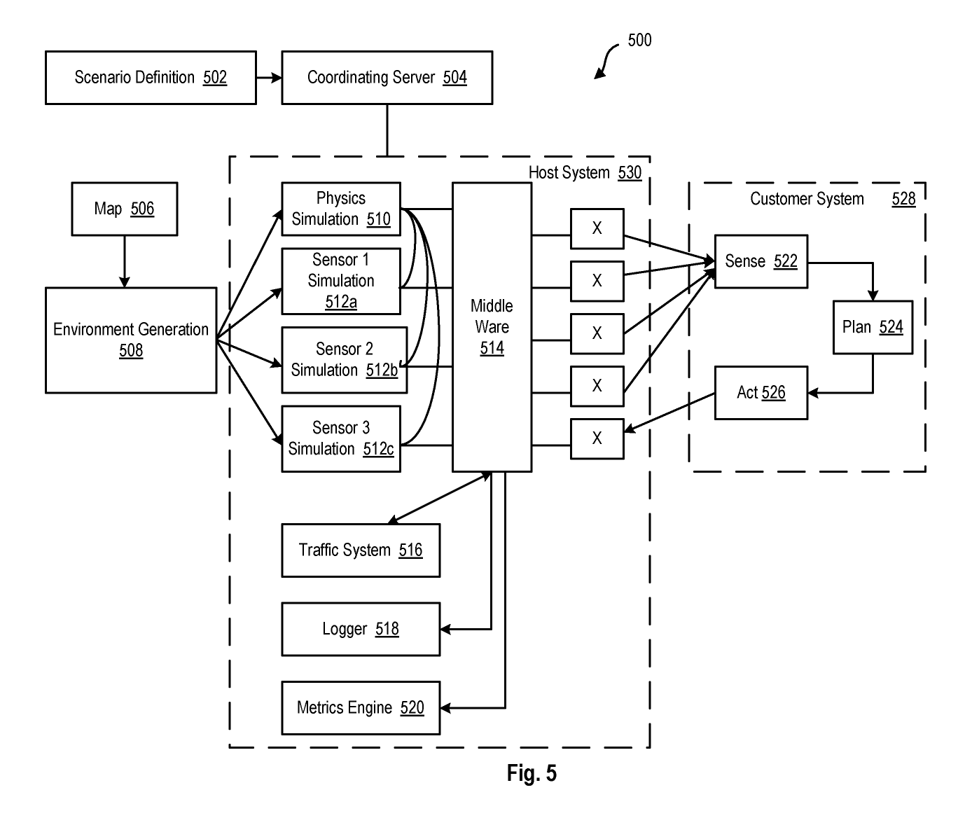

Referring now to FIG. 5, various components may be used to launch and perform a simulation in accordance with embodiments of the invention. Components of the invention may include, for example, a coordinating server 504 and at least one cosimulation process 510, 512a-c with knowledge of the 3D scene. In some embodiments, multiple cosimulation processes 510, 512a-c may work together to represent the virtual environment and perform the simulation. In certain embodiments, each of multiple cosimulation processes 510, 512a-c may be provisioned differently depending on which sensor is being simulated.

For example, in one embodiment, the simulation process 500 may begin by receiving a scenario definition 502 and/or a high-definition map 506 from a customer. The high-definition map 506 may be used in connection with environment generation processes 508 (set forth in detail in FIG. 2) to create scenes for one or more cosimulation processes 510, 512. When it is time to run the simulation, the customer may send a scenario definition 502 to the coordinating server 504. In certain embodiments, the coordinating server 504 may determine how many and which cosimulation processes 510, 512 to create based on the sensor set the customer has requested.

In some embodiments, the cosimulation processes 510. 512 may be created and connected to a middleware bus 514. The middleware bus 514 may transfer data structures between simulation system components. In certain embodiments, the middleware bus 514 may replicate state data between the cosimulation processes 510, 512a-c, traffic simulation system 516, logger system 518, and metrics engine 520. The middleware bus 514 may also receive sensor measurements from each of the cosimulation processes 510, 512a-c, translate each measurement into a data structure usable by the customer system 528, and send each measurement to one or more customer systems 528.

In some embodiments, the customer system 528 may use the data structures it receives from the simulation as a basis for determining an appropriate action 526. The customer system may then communicate to the host system 530 a requested action 526, which may be received by the host system 530, translated through the middleware bus 514, and used by at least one of the cosimulation processes 510, 512a-c to update the virtual environment.

Supporting pieces such as the traffic simulation system 516, logger 518, and metrics engine 520, may also communicate with the host system 530 middleware bus 514 for use in connection with the simulation. For example, the traffic simulation system 516 may communicate with the middleware bus 514 as the authority on the state of the traffic cars, pedestrians, and the like. That information may be replicated to and represented in the cosimulation processes 510, 512a-c, customer middleware, and supporting processes.

A logger 518 may keep track of the states represented in the virtual environment. This information may the enable the logger 518 to replay what happens in the simulation from various angles. A metrics engine 520 may evaluate the robot's performance during simulation. For example, in one embodiment, the metrics engine 520 may receive information that the robot is in a particular location (i.e., at an intersection), and that the location is prohibited because the light is red and the robot is blocking the box. In another embodiment, for example, the metrics engine 520 may analyze the data from the simulation and determine, based on the data, that the robot did not stop long enough at the stop sign.

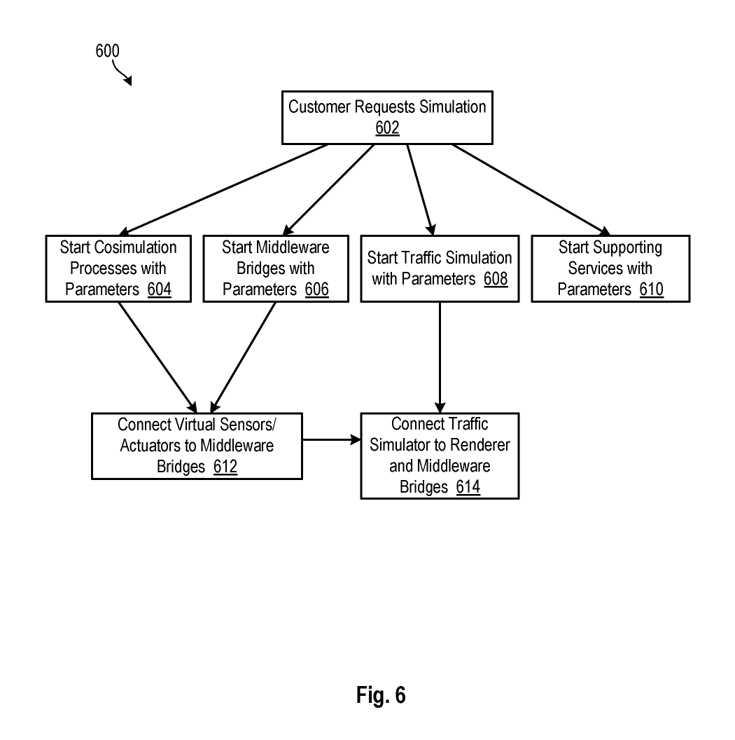

FIG. 6 depicts a process 600 for launching simulation in accordance with embodiments of the invention. As shown, a customer may request 602 simulation to begin a simulation process. The request 602 may be sent from the customer system to a central server of the simulation or provider system, and may include various parameters, such as quantity and types of sensors for testing, environment location and/or map, environment features such as time of day and weather, and other actors to be included in the environment. For each actor, the customer may also specify information about the actor's location, its dynamic state, and whether it should be customer-controlled or simulation-controlled. In some embodiments, parameters may also include information for communicating with the customer system.

Upon receiving the request 602, the cosimulation processes may automatically begin to simulate 604 a virtual environment based on one or more customer parameters. For example, each of the specified actors may be located and positioned within the virtual environment according to customer specifications. Specified virtual sensors, such as a camera for example, may also be created inside a cosimulation process.

Upon receiving the request 602, and prior to launching simulation processes, the server may also determine how to connect the various simulation components. With respect to a sensor cosimulation process, for example, some of the parameters provided by the customer may specify sensor signal formats or signal names. The server may use this same information to start 606 the middleware bridges. In one embodiment, for example, the cosimulation process may broadcast a camera on channel 6, the middleware bridge will start middleware outside the engine to receive the image from the camera on channel 6, and then the middleware bridge may send the image to the customer in an appropriate middleware program or paradigm. In certain embodiments, virtual sensors from the cosimulation processes, and actuators from the customer system, may be connected 612 to the middleware bridges to communicate with each other in this manner.

In some embodiments, the traffic simulation may then be started 608 in accordance with customer parameters. The traffic simulator may also be connected 614 to the cosimulation processes and to the middleware bridges to enable it to communicate with other simulation components. The traffic simulator may also be connected 614 to the customer bridge to enable the customer to interact with it as well.

Supporting services such as a logger and metrics engine may also be started 610 according to customer-requested and simulation-imposed parameters. These parameters may dictate, for example, how time moves inside the simulation. In certain embodiments, the simulation may be run in more than one mode. For example, one mode may run the simulation in step-fashion, similar to a turn-based video game. In this mode, all of the computations and sensor signals may be created by the simulator, and the measurements generated from the simulation may be sent back to the customer to enable the customer to decide how to respond. In certain embodiments, the simulator may wait for a customer response and a request to advance simulation before proceeding with any further simulation. In this manner, the simulator and the customer essentially “take turns” communicating.

An alternative mode of operation may run the simulation in “real-time.” In this mode, the simulation system primarily supports the customer's hardware running in real time. In this mode, the advance request may be omitted or essentially ignored as superfluous. Instead, the simulation may be run such that the time elapsed in the simulation matches the time elapsed in reality. In some embodiments, the simulation system may listen for the customer actuation signal or advance request, but may run and/or repeat the simulation regardless of whether the signal is actually received.

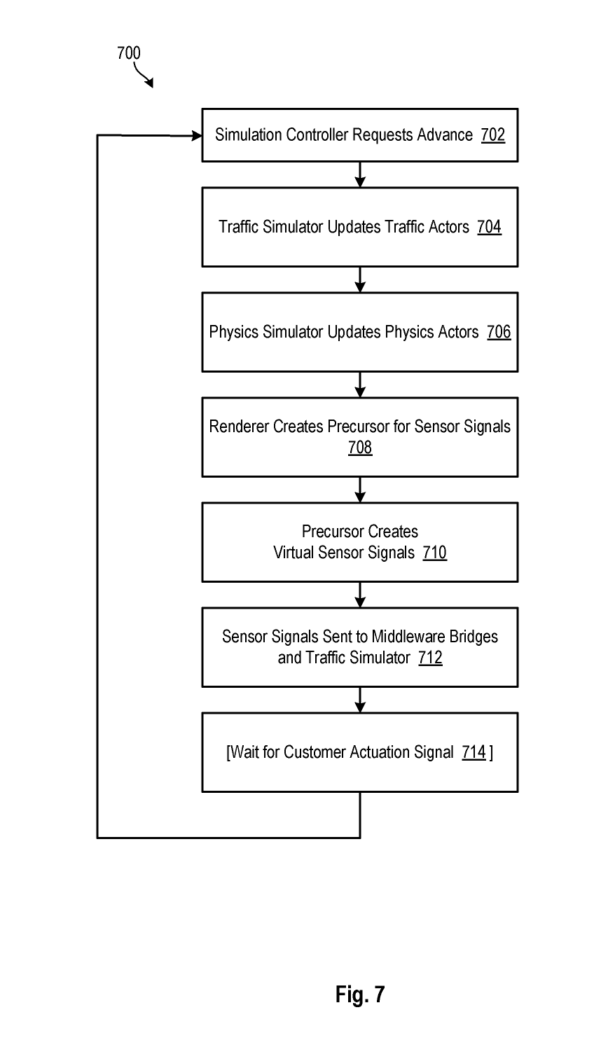

FIG. 7 illustrates one embodiment of a process 700 for running a simulation in accordance with the invention. As discussed above, the first step may include requesting 702 an advance. Depending on the execution mode (which may be determined prior to launching the simulation), this request may be made by the customer, or may happen automatically if the simulation is running in real-time mode, for example. In one embodiment, a customer advance request may include parameters, such as: advance the simulation by 0.004 second, put the throttle at 30%, and put the steering wheel at 1 degree.

Based on established or requested parameters, the positions, orientations, and look of traffic actors may be updated 704. Traffic actors may include stationary actors, such as traffic signals, as well as dynamic actors. The look of the traffic actors, such as whether headlights or brake lights are on, may also be updated 704 as requested. Anything else that would show up in the rendering of the traffic actors, such as their appearance or the way they are oriented in space, may also be updated 704.

In some embodiments, certain actors may be updated 706 by a physics simulation. In one embodiment, for example, a physics simulation may be used to determine the linear and angular accelerations of a drone at various motor voltages. A physics simulation may calculate changes in position and orientation of a customer robot over time based on customer input. Customer input for an autonomous vehicle may include, for example, information regarding throttle, brake and steering. The physics simulation may use that information to determine the state of the vehicle at the next time step. The physics simulation may thus use a dynamics model from actuator signals to reflect a change in state and may execute the state change. Other components may operate directly on state. In one embodiment, for example, a pedestrian may be simulated as position, orientation, and pose of the joints, rather than a physical simulation of muscle and bone.

Upon defining and/or determining the location and status of the actors within the virtual environment, a cosimulation process may provision or create 708 graphics and/or state information that may be used to create sensor signals and readings. Sensors may include, for example, camera, lidar, radar, location sensors, information from the physics simulation to simulate an inertial measurement unit, depth cameras, laser scanners, and the like. In certain embodiments, sensors may use knowledge of the scene model, information from the physics simulation, and/or information from completed or intermediate rendering steps to create 710 representative sensor signals.

In some embodiments, such sensor signals may be sent 712 to the middleware bridges for communication to the customer, and to the traffic simulator. If the simulation is running in Programmatic Time Mode, the simulation may wait 714 for the customer to send an actuation signal before re-running the simulation main loop. If the simulation is running in real-time mode, the simulation system may wait 714 for an actuation signal from the customer and use it if it is ready. If no actuation signal is received, the simulation main loop may automatically run again. As previously discussed, the advance request may come from the customer or from the simulation system depending on which execution mode is running. In this manner, the simulation main loop may execute continuously or intermittently during simulation.

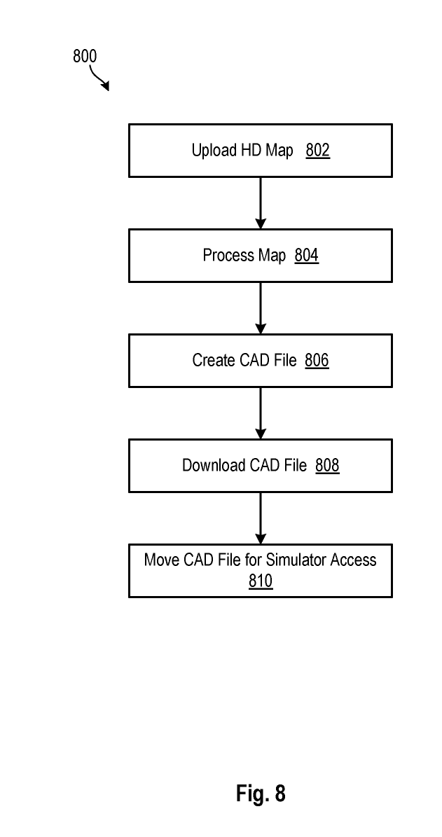

Referring now to FIG. 8, some embodiments of the invention may allow a customer to upload 802 a high-definition map for use by the simulation system. In certain embodiments, a website hosted on the simulation platform or remotely may provide a portal to receive a customer-provided map. Upon receipt by the simulation system, the map may be processed 804 to create 806 a CAD or other standardized file type. This file may be moved 810 to an appropriate place on the simulation file system for use by the simulation system.

In some embodiments, the CAD file may be downloaded 808 to the customer through the same portal or other connection. In certain embodiments, the customer system may maintain a constant or sustained connection with the simulation system through the portal for updating, or may connect with the simulation system intermittently or periodically for updating.

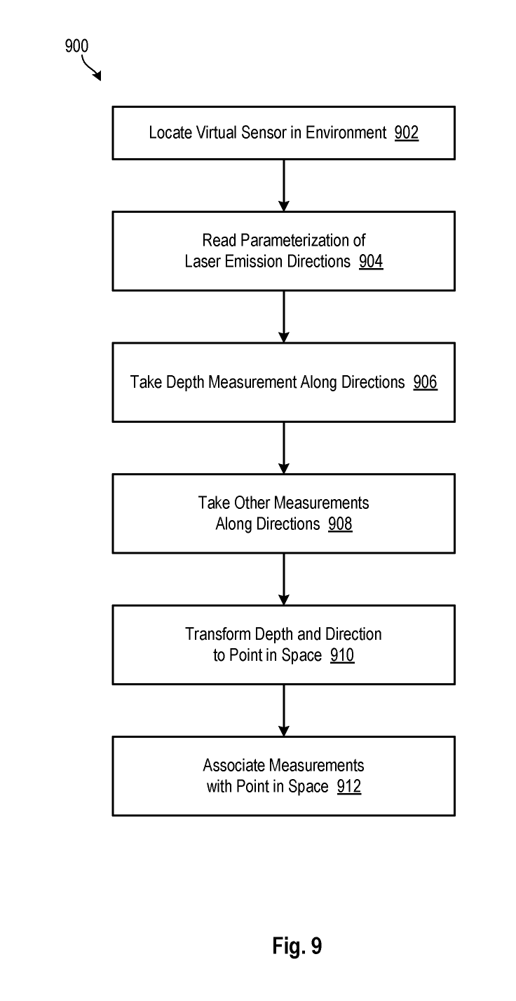

FIG. 9 illustrates a cosimulation process 900 for taking sensor measurements and creating a generalized or basic point cloud in accordance with certain embodiments of the invention. In some embodiments, a virtual sensor may be located 902 in the virtual environment. Parameterization of laser emission direction may be read 904 from data used to initialize the cosimulation process 900. A measurement may be taken 906 from the sensor to create a point. Additional measurements from other sensors or objects may also be made 908 and associated with the point. Based on these measurements, a basic point cloud may be created 910 that includes a set of x,y,z coordinates relevant to a particular sensor, such as a lidar or laser sensor. Three spatial coordinates x,y,z may be associated 912 with one measurement from a sensor.

Each point in this point cloud may be tagged with metadata that may be available in the simulation, but not necessarily provided by the sensor's measurement in reality. Such metadata may include, for example, the type of object represented by the point, a unique number associated with the object, or a classification for the object. Such metadata may also indicate whether the object is living, whether the object is solid, etc.

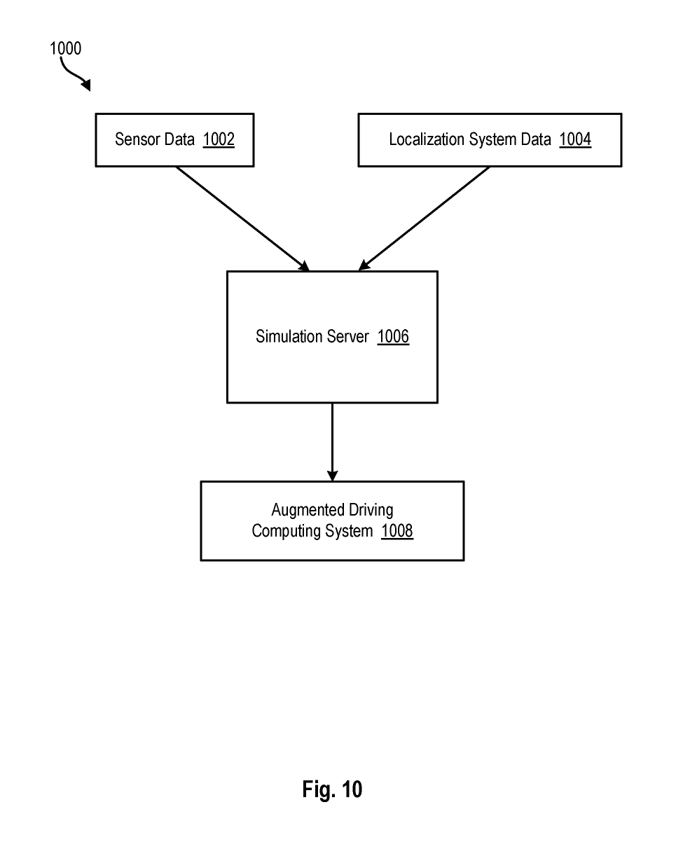

Referring now to FIG. 10, in another embodiment, a method 1000 may be provided to test an autonomous vehicle or other robot in the physical world, augmented with synthetic or hallucinated perception measurements. Physical dynamics measurements taken may be inherently accurate since the physical system is under test. Hallucinated perception measurements may be used in addition to the physical dynamics to create situations that may be prohibitively difficult or dangerous in real life.

For example, one embodiment of the invention may test an automated vehicle that ruptures a tire in heavy traffic. The automated vehicle and tire rupture may physically occur under test, and may therefore be amenable to physical measurements. Heavy traffic, on the other hand, may be hallucinated to avoid real-life danger to people and property. In this manner, embodiments of the invention may run in real-time to augment physical data from a host vehicle's sensors with data from hallucinated objects.

In operation, sensor data 1002, including a location and orientation of a vehicle platform, may be read from live measurements. In some embodiments, such measurements may be captured and/or recorded by a vehicle localization system 1004. One or more arrays of various sensors (such as lidar sensors, ultrasonic sensors, camera sensors, radar sensors, and the like), may be mounted to or otherwise associated with the vehicle. In some embodiments, in addition to capturing real sensor data 1002 from an external physical environment, such sensors may also compute a location and orientation of the sensor with respect to a virtual environment. This information may be used to calculate hallucinated sensor measurements.

A simulation server 1006, including an augmenting processor, may receive isolated portions of hallucinated sensor measurements in addition to live measurement data 1002 or localization system data 1004. For example, in some embodiments utilizing lidar or ultrasonic sensors, the simulation server 1006 may receive hallucinated measurements if a distance between the lidar or ultrasonic sensor and the hallucinated object is less than an expected real-life measurement distance. In other embodiments utilizing camera sensors, hallucinated objects may be contained on an otherwise transparent overlay such that live measurements may be taken for areas not occupied by hallucinated objects. In other embodiments utilizing radar sensors, a track for measuring hallucinated objects may be added, and/or a track for live measurements may be removed.

In any case, the simulation server 1006 may process real sensor data and hallucinated or virtual sensor information in addition to localization system data. This combined data may be used to produce augmented sensor measurements or signals. These augmented sensor measurements may be broadcast for consumption by an augmented driving computing system 1008 in accordance with embodiments of the invention.

In the above disclosure, reference has been made to the accompanying drawings, which form a part hereof, and in which is shown by way of illustration specific implementations in which the disclosure may be practiced. It is understood that other implementations may be utilized and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

While various embodiments of the present disclosure have been described above, it should be understood that they have been presented by way of example only, and not limitation. It will be apparent to persons skilled in the relevant art that various changes in form and detail can be made therein without departing from the spirit and scope of the disclosure. Thus, the breadth and scope of the present disclosure should not be limited by any of the above-described exemplary embodiments, but should be defined only in accordance with the following claims and their equivalents. The foregoing description has been presented for the purposes of illustration and description. It is not intended to be exhaustive or to limit the disclosure to the precise form disclosed. Many modifications and variations are possible in light of the above teaching. Further, it should be noted that any or all of the aforementioned alternate implementations may be used in any combination desired to form additional hybrid implementations of the disclosure.

1. A method for providing simulation testing, comprising:
receiving, from a customer, a request to generate a virtual environment for testing a robot of the customer;
automatically generating, by a service provider, the virtual environment in accordance with the request;
enabling the customer to interface with the virtual environment of the service provider to iteratively test the robot in the virtual environment and thereby generate simulation results, the simulation results reflecting interactions between the robot and the virtual environment; and
communicating, from the service provider to the customer, the simulation results.

2. The method of claim 1, wherein the service provider uses physics simulation techniques to update at least one of a position and an orientation of the robot in the virtual environment.

3. The method of claim 1, further comprising enabling the customer to control the robot in the service provider's virtual environment.

4. The method of claim 3, wherein the service provider updates at least one of a position and an orientation of the robot in the virtual environment to match at least one of a position and an orientation of the customer-controlled robot.

5. The method of claim 1, wherein the service provider updates the virtual environment in response to actions of the robot.

6. The method of claim 1, wherein the virtual environment provides sensor input data to at least one communication channel of the robot.

7. The method of claim 6, wherein the sensor input data is at least one of virtual sensor input data, real sensor input data, and a combination thereof.

8. The method of claim 1, further comprising incorporating, by the service provider, a third-party cosimulation process into the virtual environment.

9. The method of claim 1, wherein automatically generating the virtual environment comprises at least one of generating and selecting a high-definition map.

10. The method of claim 9, further comprising populating the virtual environment with at least one of a virtual object and a virtual actor present in the high-definition map.

11. The method of claim 10, further comprising generating an index associating the at least one of the virtual object and the virtual actor with at least one of an object and a feature of the high-definition map.

12. A system for providing simulation testing, comprising:
a robot of a customer;
at least one processor; and
at least one memory device operably coupled to the at least one processor and storing instructions for execution on the at least one processor, the instructions causing the at least one processor to:
receive, from a customer, a request to generate a virtual environment for testing the robot;
automatically generate the virtual environment in accordance with the request;
enable the customer to interface with the virtual environment to iteratively test the robot in the virtual environment and thereby generate simulation results, the simulation results reflecting interactions between the robot and the virtual environment; and
communicate, to the customer, the simulation results.

13. The system of claim 12, the instructions further causing the at least one processor to use physics simulation techniques to update at least one of a position and an orientation of the robot in the virtual environment.

14. The system of claim 12, the instructions further causing the at least one processor to enable the customer to control the robot in the virtual environment.

15. The system of claim 14, the instructions further causing the at least one processor to update at least one of a position and an orientation of the robot in the virtual environment to match at least one of a position and an orientation of the customer-controlled robot.

16. The system of claim 12, wherein the virtual environment provides sensor input data to at least one communication channel of the robot.

17. A computer program product for providing simulation testing, the computer program product comprising a non-transitory computer-readable storage medium having computer-usable program code embodied therein, the computer-usable program code configured to perform the following when executed by at least one processor:
receive, from a customer, a request to generate a virtual environment for testing a robot of the customer;
automatically generate, by a service provider, the virtual environment in accordance with the request;
enable the customer to interface with the virtual environment of the service provider to iteratively test the robot in the virtual environment and thereby generate simulation results, the simulation results reflecting interactions between the robot and the virtual environment; and
communicate, from the service provider to the customer, the simulation results.

18. The computer program product of claim 17, the computer-usable program code further configured to use physics simulation techniques to update at least one of a position and an orientation of the robot in the virtual environment.

19. The computer program product of claim 17, the computer-usable program code further configured to enable the customer to control the robot in the virtual environment.

20. The computer program product of claim 17, wherein the virtual environment provides sensor input data to at least one communication channel of the robot.
